(19) United States
(12) Patent Application Publication
(10) Pub. No.: US 2019/0165032 A1
(43) Pub. Date: May 30, 2019

(54) GALLIUM NITRIDE PHOTODETECTOR WITH SUBSTANTIALLY TRANSPARENT ELECTRODES

(71) Applicants: James G. Fiorenza, Carlisle, MA (US); Shrenik Deliwala, Andover, MA (US)

(72) Inventors: James G. Fiorenza, Carlisle, MA (US); Shrenik Deliwala, Andover, MA (US)

(21) Appl. No.: 16/204,424

(22) Filed: Nov. 29, 2018

Related U.S. Application Data
(60) Provisional application No. 62/593,032, filed on Nov. 30, 2017.

(51) Int. Cl. H01L 27/146; H01L 31/0368; H01L 31/105; H01L 31/108; H01L 31/032

(52) U.S. Cl. CPC H01L 27/14643; H01L 27/14632; H01L 27/14687; H01L 31/0322; H01L 31/1055; H01L 31/1085; H01L 31/03682

(57) ABSTRACT

A photodetector having a substrate, a layer gallium nitride based material supported by the substrate, and a pair of electrodes formed by a two-dimensional electron gas at an interface between the layer gallium nitride based material and a barrier layer, the pair of electrodes being substantially transparent to ultraviolet

### FIELD OF THE INVENTION

This document pertains generally, but not by way of limitation, to semiconductor devices, and more particularly, to gallium nitride photodetectors.

### BACKGROUND OF THE INVENTION

Photodetectors can be formed using semiconductor devices that convert light striking an exposed or photoreceptive area of the devices into an electrical current. The sensitivity of such devices, such as indicated by the amount of current produced per unit of incident light received or the wavelength of incident light that generates the most current, can depend on the size of the photoreceptive area and the type of material used to fabricate the such semiconductor devices. Generally, larger photoreceptive areas are able to receive more incident light to convert to an electrical current, while the bandgap of the semiconductor material used to construct a semiconductor device can determine the particular wavelengths of light that to which a device is sensitive.

The large band gap of gallium nitride-based compound semiconductors make these materials particularly useful for constructing photodetectors that are responsive to ultraviolet light. A general example of such a photodetector can be found in U.S. Pat. No. 5,677,538A to Theodore D. Moustakas and Mira Misra (hereinafter, the '538 patent). According to the '538 patent a photodetector can include a substrate with interdigitated electrodes formed on its surface. The substrate has a sapphire base layer, a buffer layer formed from a III-V nitride and a single crystal III-V nitride film. The three layers are formed by electron cyclotron resonance microwave plasma-assisted molecular beam epitaxy (ECR-assisted MBE). Use of the ECR-assisted MBE process allows control and predetermination of the electrical properties of the photodetector.

The electrodes of the '538 patent, however, are formed of opaque materials, such as aluminum and titanium. Such electrodes, when disposed over a photoreceptive area of the photodetector, can reduce the size of the area of the device that is able to receive incident light. In a photodetector is made of a layer gallium nitride (GaN) material, these opaque electrodes can block a portion of the photoreceptive layers of gallium nitride-based material from receiving incident light, such as to reduce the amount of a current that can be generated by the photodetector.

### BRIEF DESCRIPTION OF THE DRAWINGS

FIG. 1 depicts a diagram of a plan view of a photodetector fabricated from a gallium nitride-based material, according various embodiments.

FIG. 2 depicts a cross-sectional view of a photodetector fabricated from a gallium nitride-based material, according various embodiments.

FIG. 3A depicts a cross-sectional view of aspects of a photodetector fabricated from a gallium nitride-based material, according various embodiments.

FIG. 3B depicts a cross-sectional view of aspects of an etched photodetector is fabricated from a gallium nitride-based material, according various embodiments.

FIG. 3C depicts a cross-sectional view of aspects of an implanted photodetector fabricated from a gallium nitride-based material, according various embodiments.

FIG. 4 depicts a cross-sectional view of aspects of a photodetector fabricated from a gallium nitride material, according various embodiments.

FIG. 5 depicts a cross-sectional view of aspects of a photodetector fabricated from a gallium nitride-based material, according various embodiments.

FIG. 6 illustrates an example process for operating a photodetector fabricated from a gallium nitride-based material, according various embodiments.

In the drawings, which are not necessarily drawn to scale, like numerals can describe similar components in different views. Like numerals having different letter suffixes can represent different instances of similar components. The drawings illustrate generally, by way of example, but not by way of limitation, various embodiments discussed in the present document.

### DESCRIPTION OF ILLUSTRATIVE EMBODIMENTS

The present disclosure describes, among other things, a gallium nitride-based photodetector having electrodes that are substantially transparent to ultraviolet WV) light. Such photodetectors can have a larger photosensitive area that other photodetectors, such as to enable the fabrication of photodetectors that are smaller and more sensitive to incident light than other GaN-based photodetectors.

In illustrative embodiments, a GaN-based photodetector can include electrodes that are substantially transparent to UV light. Such electrodes can include, or can be formed by, a two-dimensional electron gas (2DEG) formed at an interface between two GaN-based compound semiconductors having different bandgaps. Such electrodes can enable the photodetector to generate more charge carriers per unit area of its photo receptive surface than other GaN-based photodetectors.

As used herein a GaN-based compound semiconductor material or a GaN-based semiconductor device can include a chemical compound of elements including GaN and one or more elements from different groups in the periodic table. Such chemical compounds can include a pairing of elements from group 13 (i.e., the group comprising boron (B), aluminum (Al), 20 gallium (Ga), indium (In), and thallium (TI)) with elements from group 15 (i.e., the group comprising nitrogen (N), phosphorus (P), arsenic (As), antimony (Sb), and bismuth (Bi)). Group 13 of the periodic table can also be referred to as Group III and group 15 as Group V. In an example, a GaN-based compound semiconductor device can be fabricated from GaN and aluminum indium gallium nitride (AlInGaN).

As used herein, a two-dimensional electron gas (2DEG) can include a region or channel of free electrons formed at the interface of two GaN-based compound semiconductors having different bandgaps, such as at the interface of a layer of active an GaN material and a layer of an active AlGaN material.

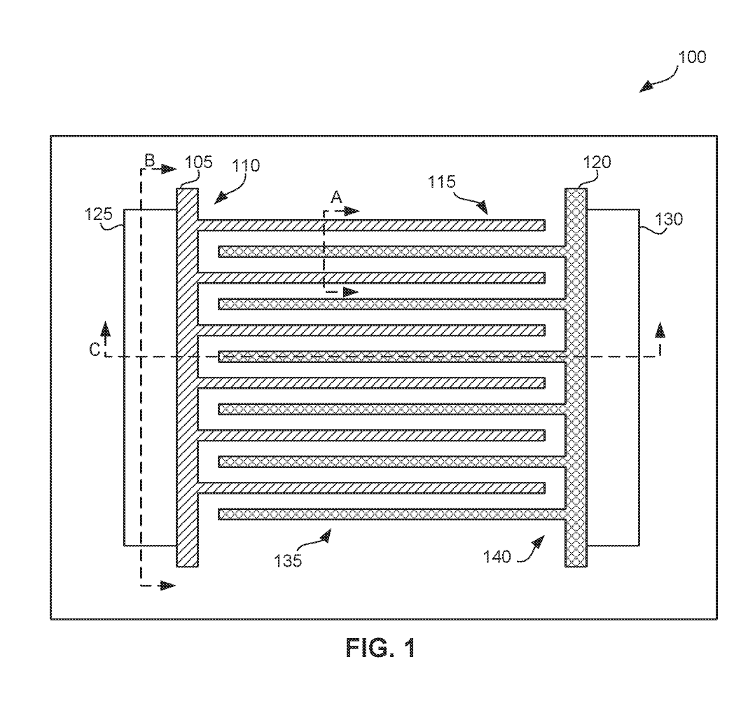

FIG. 1 depicts a diagram of a plan view of a photodetector 100 fabricated from a GaN-based material, according various embodiments. The photodetector 100 can be an example of a GaN-based photodetector, configured to generate a current in response to receiving UV light. The photodetector 100 can include control terminals 125 and 130, electrodes 110 and 140, and a photoreceptive surface (not show). The photoreceptive surface can include a surface of a layer of GaN-based material (hereinafter, “Gan layer”) configured to form a heterostructure with a barrier layer (not shown) of GaN base material. Such barrier layer can be substantially transparent to UV light, while such GaN layer can be configured or selected absorb UV light, such as to release pairs of charge carries in response to receiving one or more photons of UV light.

The control terminals 125 and 130, can include two or more metal terminals (e.g., drain, source, or gate terminals) for controlling the operation of the photodetector 100. Such terminals can include metals or metal layer materials typically used in the fabrication of GaN-based devices to interface such devices with other circuits. Such metals or metal layer materials can include any suitable electrically conductive material capable of forming an ohmic contact or other electrically conductive junction with GaN-based materials,

The electrodes 110 and 140 can each include a base region 105 or 120, and one or more fingers 115 or 135 disposed over the photoreceptive surface of the photodetector 100. In some embodiments, the base region 105 or 120 and the one or more fingers 115 or 135 can include, or can be formed by a 2DEG formed at an interface between the GaN layer and the barrier. In certain embodiments, the base region 105 or 120 can include a metal layer material or a metal contact, while the one or more fingers 115 or 135 can include, or can be formed by, a 2DEG formed at an interface between the GaN layer and the barrier.

As shown in FIG. 1, fingers of the electrodes 110 and 140 can be interdigitated, such as to cause fingers of electrode 110 to be disposed in close proximity of fingers of the electrode 140. The interdigitated fingers can be separated by a distance determined by the fabrication process used to fabricate the photodetector 100. In some embodiments, such interdigitated fingers can be separated 1 to 10 micrometers. The electrodes 110 and 140 can be electrically isolated from each other, such as to cause the electrode 110 to include a first 2DEG region and the electrode 140 to include a second, physically and electrically separate, 2DEG region. Such distinct 2DEG regions can be formed by patterning the GaN layer or barrier layer, such as to electrically deactivate, or to remove, regions of either layer around electrodes 110 or 140.

The electrodes 110 or 140 can be connected to the terminals 125 or 130, respectively, such as to couple the electrodes to other circuit components.

In operation, a first voltage can be applied to the terminal 125 and a second voltage can be applied to the terminal 130, such as to create a potential difference between the electrodes 110 and 140, such as generate an electric field between the one or more fingers 115 and 135. Such electric field can cause free charge carriers generated by UV light that impacts the GaN layer to migrate toward the electrodes 110 or 140, such as to generate an electrical current.

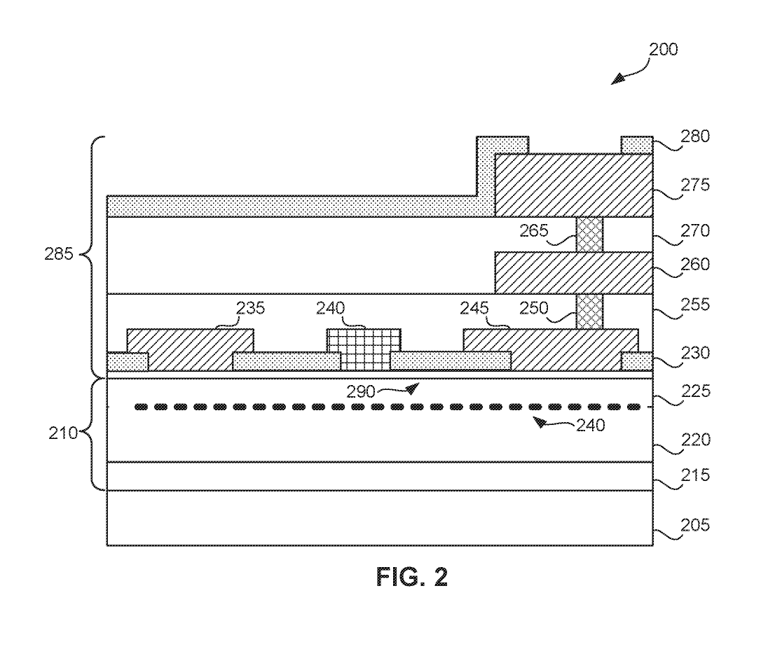

FIG. 2 depicts a cross-sectional view of a photodetector 200 fabricated from a GaN-based material, according various embodiments. The photodetector 200 can be an example of the photodetector 100. The photodetector 200 can include a substrate 205, a GaN-based device layer 210, and a metal layer 285.

The substrate 205 can include any suitable semiconductor substrate, such as a wafer of sapphire (α-Al203), GaN, GaAs, Si, SiC in any of its polymorphs (including wurtzite), AlN, InP, or similar substrate material used in the manufacture of semiconductor devices. Such substrate can be can be produced according to one or more substrate growth and processing techniques.

In some embodiments, the substrate 20 is formed from a high resistance material (e.g., a resistance in a range from approximately 10⁶ to 10¹⁴ ohms per square meter or greater). In certain embodiments, the substrate 20 can be formed from a silicon-based material, such as high resistivity single crystal silicon (e.g., from a silicon-on-insulator wafer or a bulk silicon wafer). In other embodiments, the substrate 20 can be formed from silicon carbide or other materials conventionally used in gallium nitride devices. The high resistivity substrate 20 can acts as an effective insulator, such as by having a resistivity sufficiently high to prevent short circuits in the silicon substrate 20.

In some embodiments, the GaN-based device layer 210 can be referred to as a general Aluminum Indium Gallium Nitride, such as to indicate the general group of materials that can be combined to form one or more layer of a GaN-based compound semiconductor device. Such layers can include a buffer layer 215, a GaN layer 220, and a barrier layer 225.

The buffer layer 215 can include a layer of material disposed between the substrate 205 and the GaN layer 220. Such material can reduce material islanding of the GaN-based material used to form the GaN layer 220 on the substrate 205. Such material can also prevent diffusion from the substrate 205 and manage stress on the crystalline structure of the GaN-based material, such as during formation of the GaN layer 220. In some embodiments, the buffer layer 215 can be formed from a 100 nanometer (nm) thick layer of aluminum nitride.

The GaN layer 220 can include a layer of electrically activated GaN-based material. In some embodiments, the GaN layer 220 can include a concentration of Al or In. Such concentrations of Al on In can be varied between 0 and 100% so as to tune or adjust the bandgap of the GaN layer from less than 3 electron volts (eV) to 6 eV. In some embodiments, the concentration of Al can be adjusted between 0 and 100% to adjust the bandgap of the GaN layer 220 between 3 eV and 6 eV. Such adjustments to the bandgap of the GaN layer 220 can adjust the range of wavelengths of light for which the GaN can generate charge carriers. In some embodiments, the GaN layer 220 can include a 5 micrometer thick layer an electrically activated GaN-based material, such as GaN, AlGan, or AlInGaN.

The barrier layer 225 can include AlGaN, InGaN, or gallium with nitrogen, and aluminum or indium (e.g., AlInGaN). The barrier layer 225 can be thinner than other layers in the GaN-based device layer 210. In some embodiments, the barrier layer 225 can include a 25 nanometer thick layer of AlGaN.

The GaN layer 220 and the barrier layer 225 can be epitaxial, such as to avoid destruction of the 2DEG due to defects in in the crystalline structure of the materials at their interface. Such defects can cause traps that reduce the mobility of electrons at the interface of the materials, which an inhibit the formation a 2DEG.

Generally, the barrier layer 225 can be selected to have a different bandgap than the bandgap of the GaN layer 220. In some embodiments, the bandgap of the barrier layer 225 is selected to allow UV light to pass through the barrier layer, such as to make the barrier layer invisible to UV light. Additionally, the bandgap of the GaN layer 220 can be selected to cause the photodetector to absorbe photons UV light through a surface 290 (e.g., a photoreceptive surface) of the GaN layer,such photons can cause the GaN layer to generate pairs of charge carriers electrons and holes).

The metal layer 285, can include one or more alternating layers of conductive or insulating material. In some embodiments, the metal layer 285 can include control terminals 235, 240, or 245. Such control terminals can be an example of the terminals 125 and 130, as shown in FIG. 1. The metal layer 285 can also include additional metal deposits 260 and 275, such as for connecting one or more of the control terminals 235, 240, or 250 to other circuit components. The metal layer 285 can also include metal layer contacts 250 or 265, as well as insulator or passivation material 230, 255, 270, or 280, In some embodiments, the insulator or passivation material 230, 255, 270, or 280 can be substantially transparent to UV light. In some embodiments, the insulator or passivation material 230, 255, 270, or 280 include silicon dioxide and/or silicon nitride.

According to various embodiments, the electrodes 110 or 140 can be formed by a 2DEG 240 formed at the interface of electrically activated areas of the GaN layer 220 and the barrier layer 225. In some embodiments, the barrier layer 225 can be piezoelectric, can have a lattice constant similar to, or the same as, the lattice constant of the GaN layer 220, and can have a polarization coefficient different than the GaN layer. The 2DEG can be produced by loosely bound valence electrons (e.g., the outermost electrons or those not completely within filled shells) that become detached from their atoms and move relative to the crystal lattice rather than an atomic core. Those detached electrons are generally confined to move in just two dimensions. In this case, the two dimensions are substantially parallel with the top surface of the photodetector 200.

Due to the nature of the 2DEG 240, ultraviolet light pass through the electrodes 110 and 140 to produce charge carriers in the gallium nitride region (e.g., in the GaN layer 220) underneath the electrodes. Accordingly, the top facing surface of the photodetector 200, other than those portions covered by opaque materials, such as the metal at the terminals, can contribute to producing charge carriers.

During fabrication, the 2DEG 240 can expand across an entire plane formed at the interface between the GaN layer 220 and the barrier layer 225. The electrodes 110 or 140 can be formed by restricting the 2DEG 240 to at least two distinct or electrically isolated patterned regions in such plane. Such patterned regions can be formed using one or more techniques for patterning GaN-based compound semiconductors, such as mechanical and/or chemical means, to damage the crystal lattice of the GaN based material in the GaN layer 220 or the barrier layer 225. Such damage can eliminate or prevent the 2DEG 240 from forming in areas outside of the electrodes 110 or 140. Such patterning can include removing or electrically deactivating portions of the GaN layer 220 or the barrier layer 225 at areas of where the 2DEG is be eliminated or inhibited. In some embodiments, a dopant implant, such as an Al implant, at specified locations GaN layer 220 and the barrier layer can be used to electrically deactivate GaN-based material at the interface of GaN layer or the barrier to accomplish the desired isolation. In certain embodiments, a chemical etch can remove portions of the barrier layer 225 in selected areas to achieve the desired isolation.

After patterning the photodetector 200, areas of in the plane of the interface between the GaN layer 220 and the barrier layer 225 that are outside of the electrodes 110 or 140 can be substantially devoid of the 2DEG, or can be incapably of transmitting the electrons in the 2DEG, thus effectively forming the isolated electrodes. The effectiveness of the patterning, such as the damage to crystal lattice of the GaN-based material, can be measured by measuring a sheet resistance between the electrodes 110 and 140, or the sheet resistance between deactivated areas of the interface between the GaN layer 220 and the harrier layer 225. Such sheet resistance can increase from a value in a range of 200-500 ohms/square meter to a value in a range of 10⁶ to 10¹⁴ ohms per square meter in response to such pataterning.

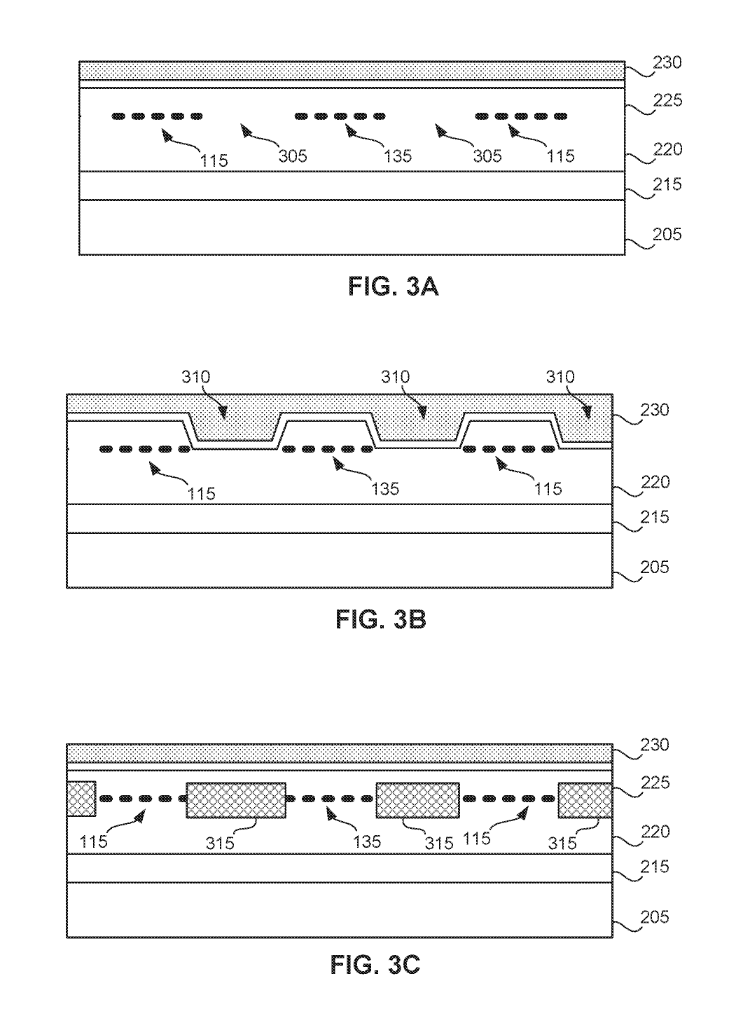

FIGS. 3A-3C show cross-sectional view of area A of an example of an implementations of the photodetector 100, as shown in FIG. 1.

FIG. 3A depicts a cross-sectional view of aspects of a photodetector fabricated from a GaN-based material, according various embodiments. In addition to the layers described in the discussion of FIG. 2, FIG. 3A depicts three 2DEG regions corresponding to fingers 115 and 135 of the electrodes 110 and 140. FIG. 3 also depicts areas 305 of the interface between the GaN layer 220 and the barrier layer 225 where the 2DEG is eliminated, or inhibited, such as to isolate the electrodes 110 and 140.

In some embodiments, a first voltage can be applied to the fingers 115, a second voltage can be applied to the fingers 135. One of the electrodes 110 or 140 can have a positive potential relative to the second electrode. Ultraviolet light that strikes the surface of the photodetector shown in FIG. 3A can pass through the electrodes 110 and 140 to be absorbed by the GaN layer 220. Absorption of the ultraviolet light by the GaN layer 220 can generate electron-hole pairs in the at near the top surface of the GaN layer. Such electron-hole pairs can be subjected to an electric field generated by the electrodes 110 and 140. The electrons generated by the absorption of the UV light tend to migrate toward the more positively charged electrode, while the holes migrate tend to migrate toward the more negatively charged electrode, thus producing a current.

FIG. 3B depicts a cross-sectional view of aspects of an etched photodetector fabricated from a GaN-based material, according various embodiments. This figure depicts an embodiment of the photodetector 100 or 200 where the electrodes 110 and 140 (e.g., fingers 115 and 135 of the electrodes) are isolated by removing portions of the barrier layer 225, such as by chemically etching cavities 310.

FIG. 3C depicts a cross-sectional view of aspects of an implanted photodetector fabricated from a GaN-based material, according various embodiments. This figure depicts an embodiment of the photodetector 100 or 200 where the electrodes 110 and 140 (e.g., fingers 115 and 135 of the electrodes) are isolated by electrically deactivating regions of at least one of the GaN layer 220 or the barrier layer 225 at the interface between the two layer. As described herein, such deactivation can be accomplished by damaging the GaN-based material, such as by implanting a deactivating dopant a indicated regions of the GaN-based material.

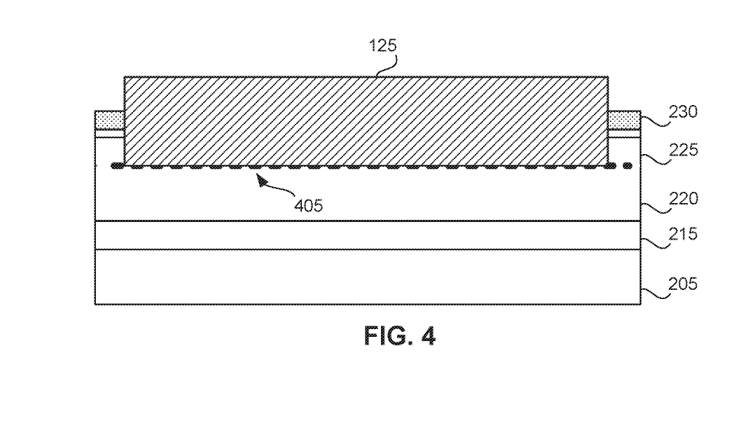

FIG. 4 depicts a cross-sectional view of aspects of a photodetector fabricated from a GaN-based material, according various embodiments. Such cross-section can be taken along the area B of an example implementation of the photodetector 100, as shown in FIG. 1. As shown in in FIG. 4, the terminal 125 can extend through the passivation layer 230 and the barrier layer 225, such as to contact the 2DEG 405, such as to connect the terminal to the electrode 110,

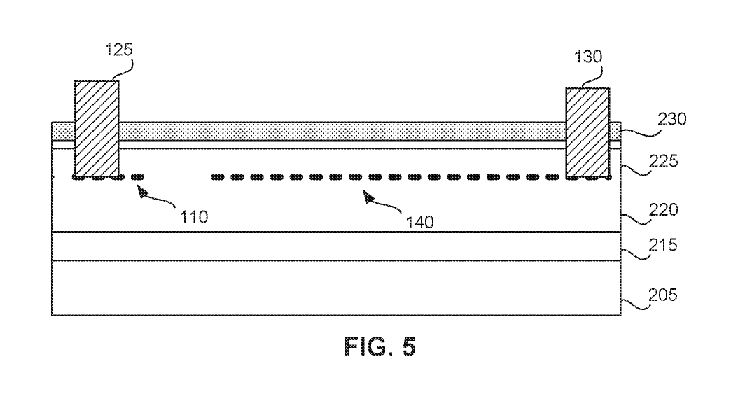

FIG. 5 depicts a cross-sectional view of aspects of a photodetector fabricated from a Gan-based material, according various embodiments. Such cross-section can be taken along the area C of an example implementation of the photodetector 100, as shown in FIG. 1. As shown in in FIG. 4, the terminals 125 and 130 be connected, such as through a metal layer contact, to 2DEG regions forming the electrode 110 and the electrode 140, respectively.

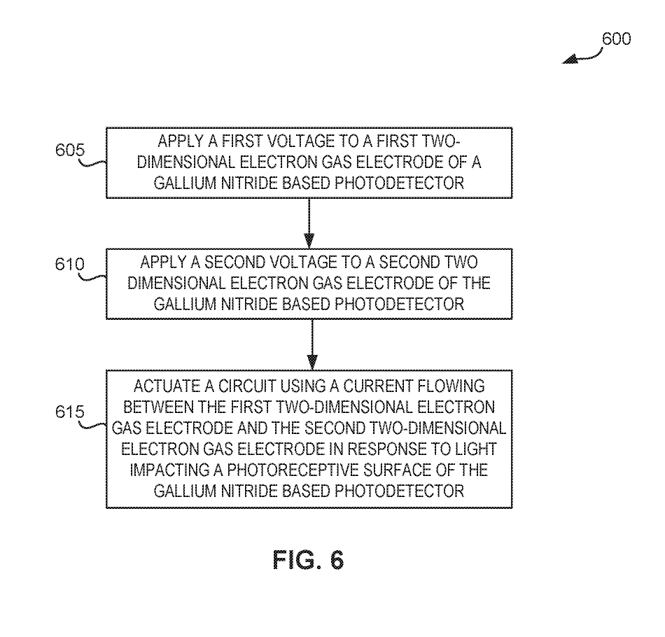

FIG. 6 illustrates an example process 600 for operating a photodetector fabricated from a gallium nitride material, according various embodiments. The photodetector can be any of the GaN-based photodetectors described herein. At 605 and 610, a potential difference can be generated between the a first 2DEG electrode and a second 2DEG electrode, such as by applying a first voltage to the first 2DEG electrode and by applying a second voltage to the second 2DEG electrode. A 615, a circuit coupled to the photodetection can be actuated using an electrical current flowing between the first 2DEG electrode and the second 2DEG electrode. Such current can be generated in response to UV light impacting a photoreceptive surface of the photodetector. Such current can be generated by UV photons that pass through the first 2DEG electrode or the second 2DEG electrode to impact the photoreceptive surface of the photodetector.

Although the above discussion discloses various exemplary embodiments of the invention, it should be apparent that those skilled in the art can make various modifications that will achieve some of the advantages of the invention without departing from the true scope of the invention.

Each of the non-limiting aspects or examples described herein can stand on its own, or can be combined in various permutations or combinations with one or more of the other examples.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein,” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The claimed invention is:

1. A photodetector comprising:
a substrate;
a layer gallium nitride based material supported by the substrate; and
a pair of electrodes formed by a two-dimensional electron gas at an interface between the layer gallium nitride based material and a barrier layer, the pair of electrodes being substantially transparent to ultraviolet light.

2. The photodetector of claim 1 wherein the layer gallium nitride based material is configured to produce electron-hole pairs when subjected to ultraviolet light.

3. The photodetector of claim 1, wherein layer gallium nitride based material has a first bandgap and the barrier layer comprises a gallium nitride based material having a second bandgap.

4. The photodetector of claim 3, wherein the layer gallium nitride based material comprises gallium nitride and the barrier layer comprises aluminum gallium nitride.

5. The photodetector of claim I, wherein pair of electrodes are formed by patterning at least one of the layer gallium nitride based material and the buffer layer to inhibit formation of the two-dimensional electron gas outside of the pair of electrodes.

6. The photodetector of claim 1 wherein the pair of electrodes comprises a plurality of interdigitated electrodes.

7. The photodetector of claim 1, at least one of the layer gallium nitride based material or the barrier layer comprises a bandgap tuning element.

8. The photodetector of claim 7, wherein the bandgap tuning element is at least one of aluminum or indium.

9. A light detector for detecting ultraviolet light, the detector comprising:
an aluminum indium gallium nitride layer configured to receive ultraviolet light and to provide at least one charge carrier in response to the received ultraviolet light; and
a two-dimensional electron gas at an interface of the Aluminum Indium to Gallium Nitride layer and a layer adjacent to the Aluminum Indium Gallium Nitride layer, the electron gas including a first region and a second region electrically isolated from the first region, wherein the first region and the second region attract the at least one charge carrier.

10. The light detector of claim 9, wherein the received ultraviolet light is received from a direction of the layer adjacent to the Aluminum Indium Gallium Nitride layer, and wherein the two-dimensional electron gas is transparent to the received ultraviolet light.

11. The light detector of claim 10, further comprising an insulating region formed by damaging the Aluminum Indium Gallium Nitride layer, the insulating region providing electrical insulation between the first region and the second region of the two-dimensional electron gas.

12. The light detector of claim 10, wherein the first region and the second region form a pair of interdigitated electrodes.

13. The light detector of claim 10, further comprising an insulating region formed by chemically etching the Aluminum Indium Gallium Nitride layer, the insulating region providing electrical insulation between the first region and the second region of the two-dimensional electron gas.

14. The light detector of claim 10, further comprising an insulating region formed by implanting ions in the Aluminum Indium Gallium Nitride layer, the insulating region providing electrical insulation between the first region and the second region of the two-dimensional electron gas.

15. The light detector of claim 10, further comprising an insulating region formed by damaging the Aluminum Indium Gallium Nitride layer, wherein damaging the Aluminum Indium Gallium Nitride layer increases a sheet resistance to of the insulating material by a factor of at least one thousand, the insulating region providing electrical insulation between the first region and the second region of the two-dimensional electron gas.

16. The light detector of claim 10, wherein the Aluminum indium Gallium Nitride layer includes an AlGaN layer having an aluminum concentration that is lower than an aluminum concentration of the layer adjacent to the GaN layer.

17. The light detector of claim 10, wherein the Aluminum Indium Gallium Nitride layer includes a GaN layer.

18. A method of operating a gallium nitride based photodetector, the method comprising:
applying a first voltage to a first two-dimensional electron gas electrode of the gallium nitride based photodetector;
applying a second voltage to a second two dimensional electrode gas electrode of the gallium nitride based photodetector; and
actuating a circuit using a current flowing between the first two-dimensional electron gas electrode and the second two-dimensional electron gas electrode in response to light impacting a photoreceptive surface of the gallium nitride based photodetector.

19. The method of claim 18, wherein the current is generated by photons that pass through the first two-dimensional electron gas electrode or the second two-dimensional electron gas electrode to impact the photoreceptive surface of the photodetector.
